(19) United States
(12) Patent Application Publication
(10) Pub. No.: US 2025/0338401 A1
(43) Pub. Date: Oct. 30, 2025

(54) THREE-DIMENSIONAL PRINTING ON PRINTED CIRCUIT BOARD

(71) Applicant: Toyota Motor Engineering & Manufacturing North America, Inc., Plano, TX (US)

(72) Inventors: Feng Zhou, Ann Arbor, MI (US); Tianzhu Fan, Houston, TX (US); Ercan Mehmet Dede, Ann Arbor, MI (US); Jae Seung Lee, Ann Arbor, MI (US)

(21) Appl. No.: 18/648,557

(22) Filed: Apr. 29, 2024

(51) Int. Cl. H05K 1/14; H05K 1/02; H05K 3/00; H05K 7/20

(52) U.S. Cl. CPC H05K 1/142; H05K 1/0203; H05K 3/0044; H05K 7/20254

(57) ABSTRACT

Systems, methods, and other embodiments described herein relate to a fabrication procedure to enable a 3D printing technique for a printed circuit board (PCB). In one embodiment, a circuit board assembly includes a first substrate, a second substrate, and a device. The first substrate includes a first surface and a second surface opposite the first surface. The first substrate has through holes. The second substrate is within the through holes. The second substrate is fused to the first substrate using a high temperature-high pressure process. The second substrate has a first top surface and a pocket. The device is positioned within the pocket. The device has a second top surface that is flush with the first surface and the first top surface. The device bonds to the second substrate. The first surface, the first top surface, and the second top surface are adhesive due to a surface treatment.

### FIELD

The subject matter described herein relates in general to preparing a printed circuit board to be receptive to 3D printed material.

### BACKGROUND

Some printed circuit boards may have a top surface that is uneven or may have gaps between various substrates and components. Three-dimensional printing onto an uneven surface may cause the three-dimensional material to warp or have air bubbles, thus preventing the three-dimensional material from securely adhering to the top surface.

### SUMMARY

In one respect, the subject matter presented herein relates to a printed circuit board (or a circuit board assembly) that is receptive to 3D printed material. The circuit board assembly includes a first substrate that has a first surface and a second surface opposite the first surface. The first substrate has one or more through holes. The circuit board assembly includes a second substrate within the one or more through holes. The second substrate fuses to the first substrate using a high temperature-high pressure process and the second substrate has a first top surface and a pocket. The circuit board assembly includes one or more devices positioned within the pocket and having a second top surface that is flush with the first surface and the first top surface. The one or more devices bond to the second substrate. The first surface, the first top surface, and the second top surface are adhesive due to a surface treatment.

In another respect, the subject matter presented herein relates to a printed circuit board (or a circuit board assembly) that is receptive to 3D printed material. A circuit board assembly includes a first substrate that has a first surface and a second surface opposite the first surface. The first substrate has one or more through holes. The circuit board assembly includes a second substrate within the one or more through holes. The second substrate has a first top surface and a pocket. The circuit board assembly includes a third substrate that fills a gap between the first substrate and the second substrate. The third substrate has a second top surface. The third substrate fuses to the first substrate and the second substrate using a high temperature-high pressure process. The circuit board assembly includes one or more devices positioned within the pocket. The one or more devices have a third top surface that is flush with the first surface, the first top surface, and the second top surface. The one or more devices are bonded to the second substrate. The first surface, the first top surface, the second top surface, and the third top surface are adhesive due to a surface treatment.

In another respect, the subject matter presented herein relates to a method for preparing a printed circuit board (or a circuit board assembly) to be receptive to 3D printed material. The method includes drilling one or more through holes in a first substrate. The first substrate has a first surface and a second surface opposite the first surface. The method includes filling the one or more holes with a second substrate. The second substrate has a first top surface. The method includes fusing the first substrate and the second substrate using a high temperature-a high pressure process, polishing the first surface and the first top surface, etching a pocket into the second substrate, and embedding a device into the pocket. The device has a second top surface and the method further includes applying a surface treatment to the first surface, the first top surface, and the second top surface.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIGS. 1A-1J are an example of a printed circuit board (PCB) assembly that is receptive to 3D printed material and a method for generating the PCB assembly.

FIGS. 2A-2J are another example of a PCB assembly that is receptive to 3D printed material and a method for generating the PCB assembly.

FIGS. 3A-3B are a side view and a top view of a circuit board assembly.

FIG. 4 is an example of a circuit board assembly with an anodized frame and an air trench.

FIG. 5 is an example of a circuit board assembly with pin fins.

FIG. 6 is a flowchart illustrating one embodiment of a method associated with generating a PCB assembly that is receptive to 3D printed material.

### DETAILED DESCRIPTION

Systems, methods, and other embodiments associated with systems and methods relating to a fabrication procedure of compact power electronics substrate that enable 3-dimensional (3D) printing techniques for printed circuit board (PCB) are disclosed. Combining a 3D-printed circuit board (PCB) such as a multi-layer PCB with a non-3D printed circuit board (PCB) provides many advantages including a reduction in costs, less dependency on third parties for component supply, and shorter turnaround time. A non-3D-printed PCB refers to a PCB that has been manufactured using methods other than 3D printing. As such and as an example, a non-3D-printed PCB may be conventionally fabricated.

Bonding 3D printed material to a non-3D-printed PCB can be difficult due to gaps between components in the non-3D-printed PCB, uneven surfaces of the non-3D-printed PCB, and/or the surfaces of the non-3D-printed PCB being too slick or slippery, making adhesion difficult. Applying a 3D-printed PCB to such a non-3D-printed PCB may result in the interface of the combined 3D-printed PCB and non-3D-printed PCB being uneven and/or rough. This may lead to the combined 3D-printed PCB and non-3D-printed PCB having poor, unreliable, and/or unpredictable performance.

Accordingly, systems, methods, and other embodiments associated with preparing a PCB that is receptive and can adhere to a 3D-printed PCB are disclosed. The system is a PCB assembly that includes a first substrate that has a first surface (also known as a top surface) and a second surface (also known as a bottom surface) opposite the first surface. The first substrate has one or more through holes extending from the first surface through the second surface. The first substrate may be made of electrically-insulated materials such as a resin, e.g., FR4 (Flame Retardant 4), ceramics, glass, epoxy, polymer, composite materials of the above, or any other suitable electrically-insulated material(s). The PCB assembly includes a second substrate located inside the one or more through holes. As an example, the second substrate may be a metal such as copper. In other words, the second substrate may be copper-based. In a case where the first substrate is a resin, the second substrate may be fused to the first substrate using a high temperature-high pressure process. In a case where the first substrate is electrically-insulated metal (due to a treatment) such as an anodized aluminum, the printed circuit board assembly may include a third substrate, which may be a resin such as FR4, between the first and second substrates. The second substrate has a first top surface and a pocket for housing devices. The PCB assembly has one or more devices, each positioned within one of the pockets. Each device has a second top surface that is flush with the first surface and the first top surface, and each device is bonded within the respective pocket to the second substrate. The first surface, the first top surface, and the second top surface are adhesive due to a surface treatment. The surface treatment may be laser etching, machine etching, and/or chemical etching of the first surface, the first top surface, and the second top surface. The top surface of the PCB assembly may include the first surface, the first top surface, the second top surface, and a top surface of the substrate if being used. Thus, the top surface of the PCB assembly may be even, without any gaps, and roughened such that the top surface of the printed circuit board is adhesive such that 3D printed material can adhere to the top surface of the PCB.

The embodiments disclosed herein present various advantages over conventional technologies. First, the embodiments can provide a PCB assembly with an even surface, no gaps between devices and substrates, and an adhesive surface for 3D printed material to adhere to. As such, 3D-printed PCB and PCB assembly may be less likely to separate. Second, the embodiments of the 3D-printed PCB and PCB assembly may be more reliable and may provide more consistent results.

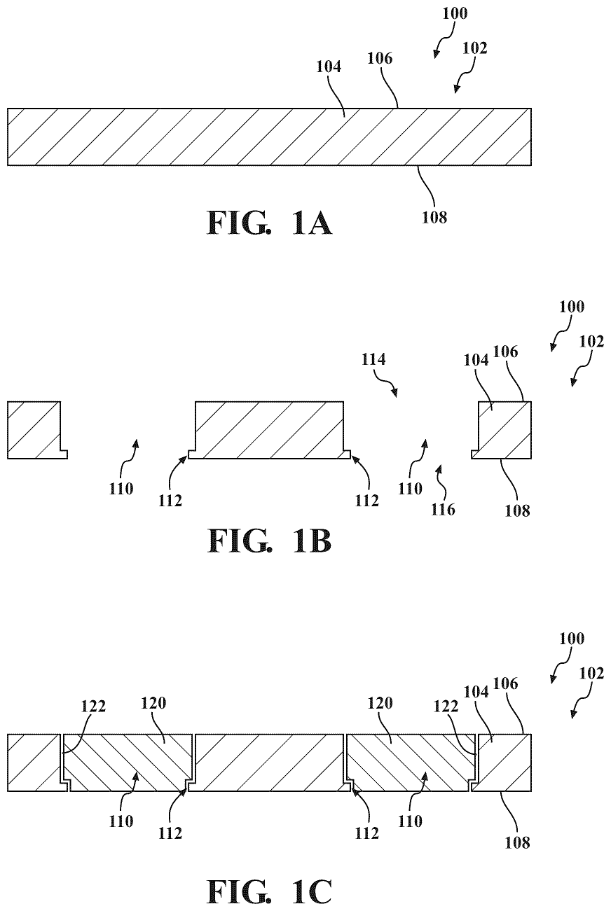

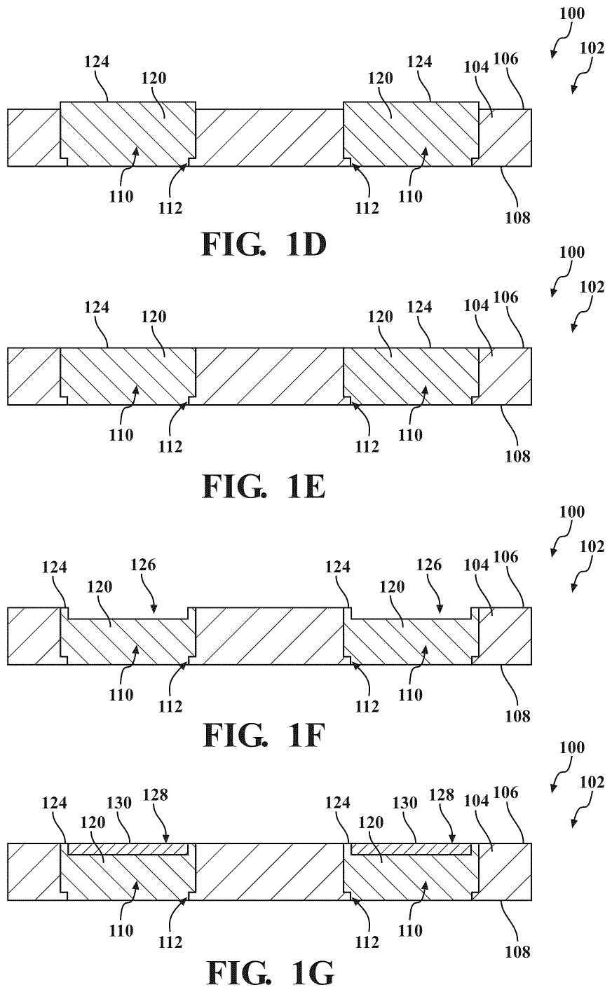

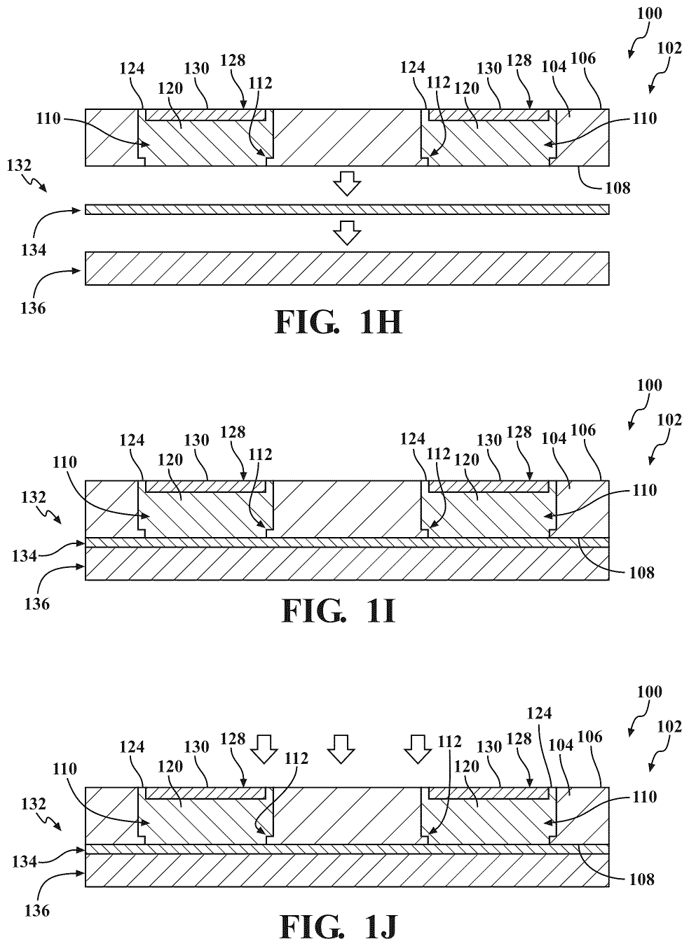

Detailed embodiments are disclosed herein; however, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-6, but the embodiments are not limited to the illustrated structure or application.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details.

FIGS. 1A-1J are an example of a PCB assembly 100 that is receptive to 3D printed material and a method 102 for generating the PCB assembly 100. The order of the steps in the method 102 below is an example. As such, the steps of the method 102 may implemented in any suitable order. As shown in FIG. 1A and as a first step, the PCB assembly 100 may include a first substrate 104. The first substrate 104 has a first surface 106 and a second surface 108 opposite the first surface 106. The first substrate 104 may be a high temperature resin such as FR4, which is a suitable PCB base material made from flame retardant epoxy resin and glass fabric composite. As shown in FIG. 1B and as a second step, the method 102 includes drilling one or more through holes 110 through the first substrate 104 using as an example, a mechanical drill bit and/or a laser. Through holes 110 are holes passing through the first surface 106 and the second surface 108 of the first substrate 104 as shown in FIG. 1B. The through holes 110 may include a step (or a lip) 112 such that a first opening 114 of the through hole 110 at the first surface 106 is larger than a second opening 116 of the through hole 110 at the second surface 108.

As shown in FIG. 1C and as a third step, the method 102 includes filling the through holes 110 with a second substrate 120. As an example, the second substrate 120 may be a copper (or metal) substrate and/or a copper (or metal) graphite composite layer. The through holes 110 may still contain a gap 122 between the first and second substrates 104, 120. As such, as shown in FIG. 1D and as a fourth step, the method 102 includes applying a high temperature-high pressure process to the first and second substrates 104, 120. This high temperature-high pressure process causes the first substrate 104 such as the FR4 to melt and close any gaps between the first and second substrates 104, 120 as shown in FIG. 1D above. The second substrate 120 has a first top surface 124.

As an example and as shown in FIG. 1E, the method 102 includes polishing the first surface 106 and the first top surface 124 such that the first surface 106 and the first top surface 124 are flush. As shown in FIG. 1F, the PCB assembly 100 includes pockets 126. More specifically, the second substrate 120 has one or more pockets 126. The method 102 includes etching or milling the second substrate 120 to create pockets 126 in the first top surface 124. Each pocket 126 is sized to house (or hold) a device.

As an example and as shown in FIG. 1G, the method 102 includes placing devices 128 in the pockets 126 and bonding the devices 128 to the second substrate 120. The devices 128 may include a second top surface 130. As an example, the devices 128 may be power devices such as IGBT (Insulated-Gate Bipolar Transistor), MOSFET (Metal Oxide Silicon Field Effect Transistors), and/or diodes. The power devices can be made by Silicon, Silicon Carbide, Gallium nitride, Gallium oxide, or other semiconductors. As another example, the devices 128 may include any suitable electronic device such as a sensor or any suitable low voltage device. The method 102 includes bonding the device 128 to the second substrate 120 using at least one of soldering, TLP (transient liquid phase) bonding, silver sintering, copper sintering, and/or nanowire bonding.

As an example and as shown in FIG. 1H, the method 102 may include bonding a cooling assembly 132 to the second surface 108. The cooling assembly 132 may include a cold plate 136 and a bonding layer 134. The method 102 may include bonding the cold plate 136 to the second surface 108 using an electrically insulated material such a polymer-based material, any suitable glue, and/or any suitable thermal conductive material as the bonding layer 134. As an example, the method 102 may include bonding the cold plate 136 to the second surface 108 using a pressurized process.

As an example and as shown in FIG. 1I, the method 102 may include applying a surface treatment to the first surface 106, the first top surface 124, and the second top surface 130. The surface treatment roughens the first surface 106, the first top surface 124, and the second top surface 130 such that the first surface 106, the first top surface 124, and the second top surface 130 are adhesive and 3D printing material can adhere to the first surface 106, the first top surface 124, and the second top surface 130. The surface treatment may include laser treatment, plasma treatment, mechanical treatment, or chemical treatment processes. The laser treatment process may include laser etching of the surface, the plasma treatment process may include plasma etching of the surface, the mechanical treatment process may include mechanical etching of the surface, and the chemical treatment process may include chemical etching of the surface.

As an example and as shown in FIG. 1J, the method 102 may include 3D printing on top of the PCB assembly 100. In other words, the method 102 may include 3D printing on top of the first surface 106, the first top surface 124, and the second top surface 130. As such, the 3D printed layer may be fixed to the first surface 106, the first top surface 124, and the second top surface 130. The 3D printing process may utilize one or more printers capable of outputting polymer-based ink, ceramics-based ink, metal-based ink, or carbon-based ink. As such, the 3D printed layer may be a combination of polymer-based material, ceramics-based material, metal-based material, and carbon-based material.

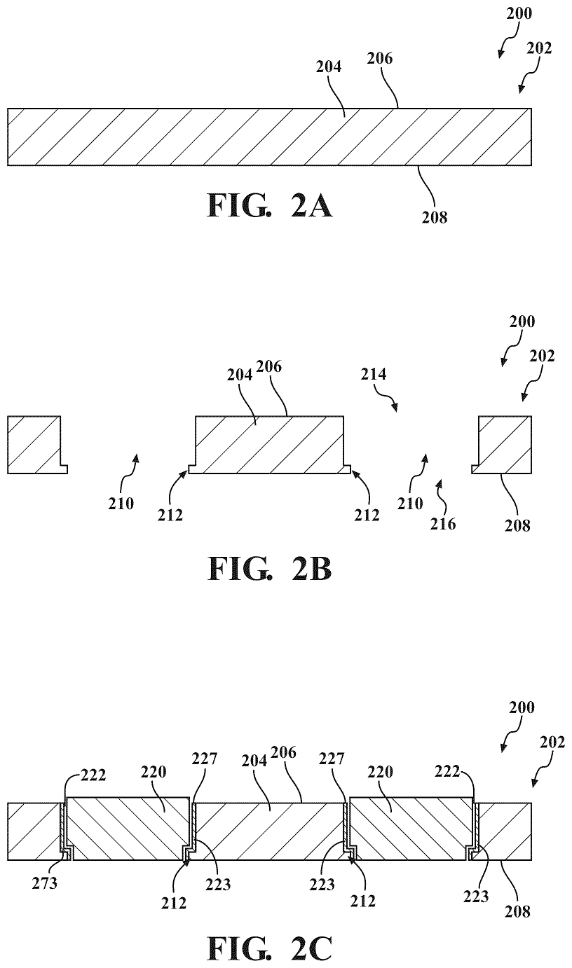

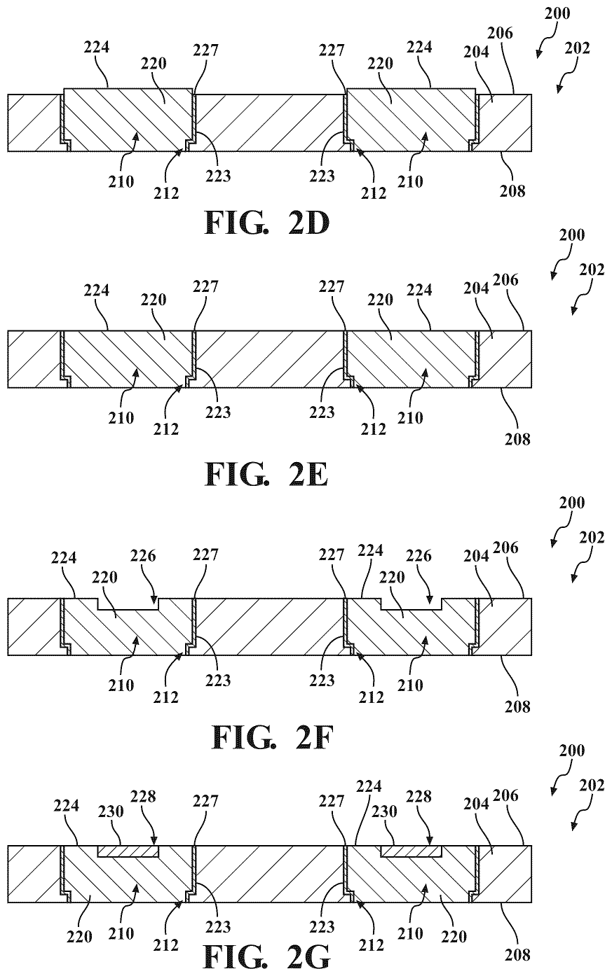

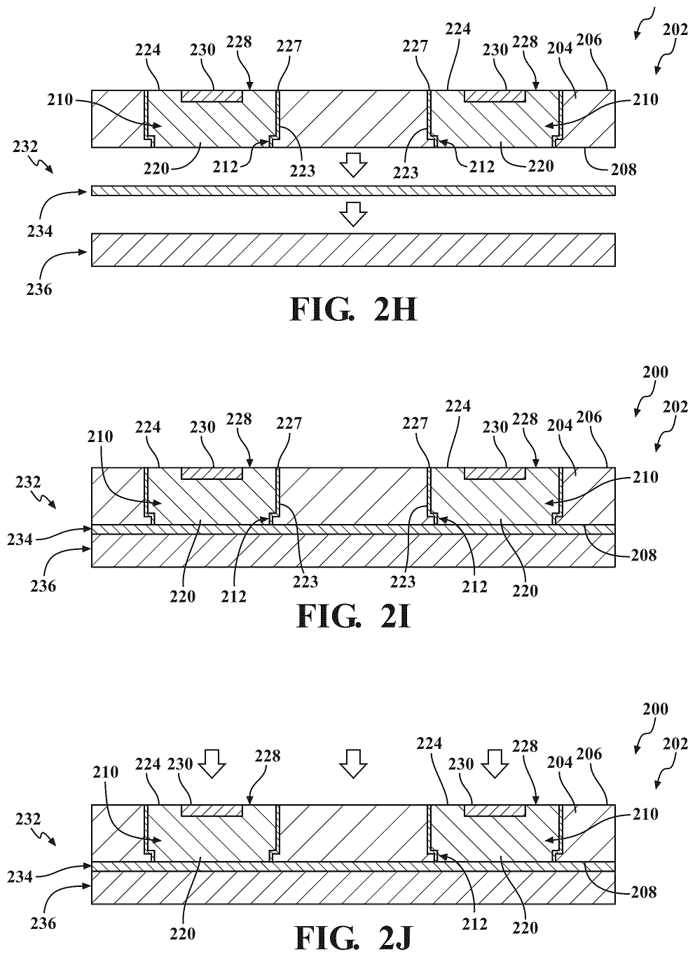

FIGS. 2A-2J are another example of a PCB assembly 200 that is receptive to 3D printed material and a method 202 for generating the PCB assembly 200. The order of the steps in the method 202 below is an example. As such, the steps of the method 202 may implemented in any suitable order. As shown in FIG. 2A and as a first step, the PCB assembly 200 may include a first substrate 204. The first substrate 204 has a first surface 206 and a second surface 208 opposite the first surface 206. The first substrate 204 may be any suitable electrically-insulated substrate such as anodized aluminum. As an example, the aluminum substrate may be standard anodized on the first surface 206 and hard anodized on the second surface 208, to make the first surface 206 and the second surface 208 electrically-insulated in general. As shown in FIG. 2B and as a second step, the method 202 includes drilling one or more through holes 210 through the first substrate 204 using as an example, a mechanical drill bit and/or a laser. Through holes 210 are holes passing through the first surface 206 and the second surface 208 of the first substrate 204 as shown in FIG. 2B. The through holes 210 may include a step (or a lip) 212 such that a first opening 214 of the through hole 210 at the first surface 206 is larger than a second opening 216 of the through hole 210 at the second surface 208.

As shown in FIG. 2C and as a third step, the method 202 includes filling the through holes 210 with a second substrate 220. The second substrate 220 has a first top surface 224. As an example, the second substrate 220 may be a copper (or metal) substrate, and/or a copper (or metal) graphite composite layer. The through holes 210 contain a gap 222 between the first and second substrates 204, 220. The method 202 includes filling the gap 222 with a third substrate 223. The third substrate 223 has a third top surface 227. The third substrate 223 may be made of any suitable electrically-insulated materials such as FR4. As shown in FIG. 2D and as a fourth step, the method 202 includes applying a high temperature-high pressure process to the first and second substrates 204, 220 as well as the third substrate 223. This high temperature-high pressure process causes the third substrate 223 to melt and close any gaps 222 between the first and second substrates 204, 220 as shown in FIG. 2D above.

As an example and as shown in FIG. 2E, the method 202 includes polishing the first surface 206, the first top surface 224, and the third top surface 227 such that the first surface 206, the first top surface 224, and the third top surface 227 are flush. As shown in FIG. 2F, the PCB assembly 200 includes pockets 226. More specifically, the second substrate 220 has one or more pockets 226. The method 202 includes etching or milling the second substrate 220 to create pockets 226 in the first top surface 224. Each pocket 226 is sized to house (or hold) a device.

As an example and as shown in FIG. 2G, the method 202 includes placing devices 228 in the pockets 226 and bonding the devices 228 to the second substrate 220. The devices 228 may include a second top surface 230. As an example, the devices 228 may be power devices such as IGBT (Insulated-Gate Bipolar Transistor), MOSFET (Metal Oxide Silicon Field Effect Transistors), and/or diodes. The power devices can be made by Silicon, Silicon Carbide, Gallium Nitride, Gallium Oxide, or other semiconductor materials. As another example, the devices 228 may include any suitable electronic device such as a sensor or any suitable low voltage device. The method 202 includes bonding the device 228 to the second substrate 220 using at least one of soldering, TLP (transient liquid phase) bonding, silver sintering, copper sintering, and/or nanowire bonding.

As an example and as shown in FIG. 2H, the method 202 may include bonding a cooling assembly 232 to the second surface 208. The cooling assembly 232 may include a cold plate 236 and a bonding layer 234. The method 202 may include bonding the cold plate 236 to the second surface 208 using the bonding layer 234 which may be an electrically insulated material such as a polymer-based material, any suitable glue, and/or any suitable thermal conductive material. As an example, the method 202 may include bonding the cold plate 236 to the second surface 208 using a pressurized process.

As an example and as shown in FIG. 2I, the method 202 may include applying a surface treatment to the first surface 206, the first top surface 224, the second top surface 230, and the third top surface 227. The surface treatment roughens the first surface 206, the first top surface 224, the second top surface 230, and the third top surface 227 such that the first surface 206, the first top surface 224, the second top surface 230, and the third top surface 227 are adhesive and 3D printing material can adhere to the first surface 206, the first top surface 224, the second top surface 230, and the third top surface 227. The surface treatment may include laser treatment, plasma treatment, mechanical treatment, or chemical treatment processes, or other processes.

As an example and as shown in FIG. 2J, the method 202 may include 3D printing on top of the PCB assembly. In other words, the method 202 may include 3D printing on top of the first surface 206, the first top surface 224, the second top surface 230, and the third top surface 227. In other words, the 3D printed layer may be fixed to first surface 206, the first top surface 224, the second top surface 230, and the third top surface 227. The 3D printing process may utilize one or more printers capable of outputting polymer (or ceramics)-based ink and/or metal (or carbon)-based ink. As such, the 3D printed layer may be a combination of polymer (or ceramics)-based material and metal (or carbon)-based material.

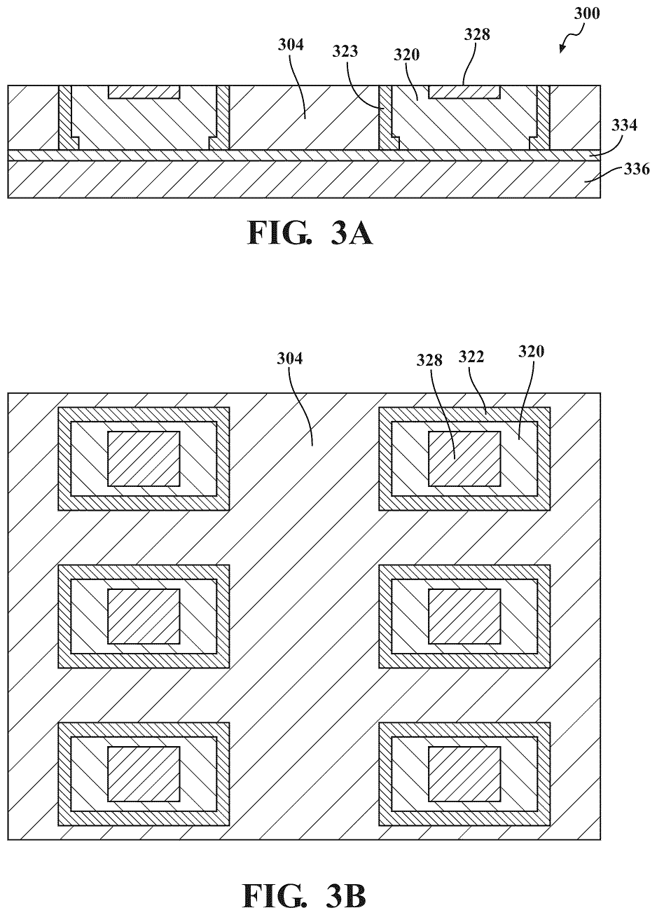

Referring now to FIGS. 3A-3B, a side view and a top view of an example of a PCB assembly 200. In this example, an anodized aluminum framed assembly 300 is shown. FIG. 3A shows a side view of the anodized aluminum framed assembly 300 which includes a first substrate of anodized aluminum 304, a second substrate of copper 320, a third substrate of a resin like FR4 323, a power device 328 in the second substrate of copper 320, a bonding layer 334, and a cold plate 336. In FIG. 3B, a top view of the anodized aluminum framed assembly 300 shows the first substrate of anodized aluminum 304, the second substrate of copper 320, the third substrate of resin like FR4 322 separating the first substrate of anodized aluminum 304 from the second substrate of copper 320, and devices 328 in the second substrate of copper 320.

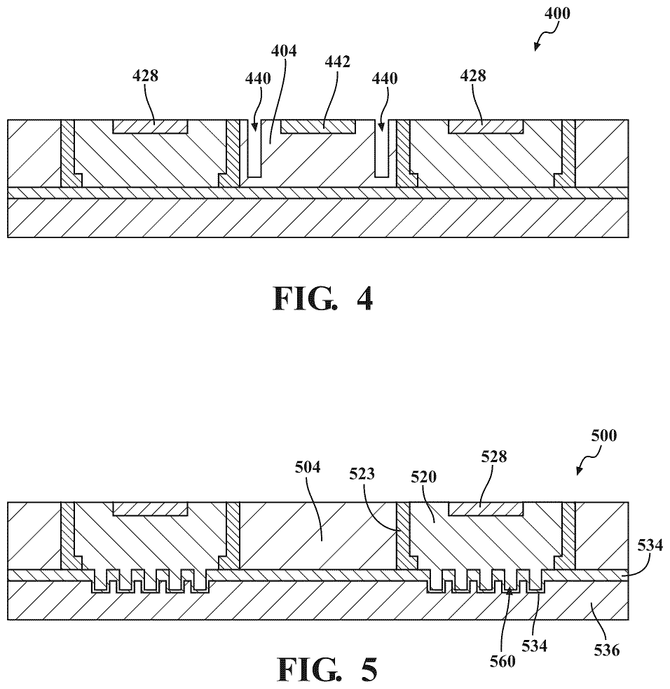

FIG. 4 shows an example of a PCB assembly 400 with an air trench 440. Circuit boards and PCB assemblies may include temperature-sensitive devices 428 and heat emitting devices 442 such as a power source in close proximity. The performance of a temperature-sensitive device 428 may be impacted by the temperature of an area surrounding the temperature-sensitive device 428. As an example and so as to prevent a degraded performance of a temperature-sensitive device 428, particularly a heat-sensitive device, the PCB assembly 400 may include air trenches 440 in a first substrate 404 to separate the temperature-sensitive device 428 from a heat emitting device 442 and assist in dissipating heat within the PCB assembly 400.

FIG. 5 shows an example of a PCB assembly 500 with pin fins 560. The PCB assembly includes a first substrate 504, a second substrate 520, a third substrate 523, a device 528, pin fins 560, a bonding layer 534, and a cold plate 536. The pin fins 560 assist in transferring heat from the second substrate 520 to the cold plate 536. This arrangement or configuration may assist in temperature management of the PCB assembly 500 and keeping the PCB assembly 500 cool.

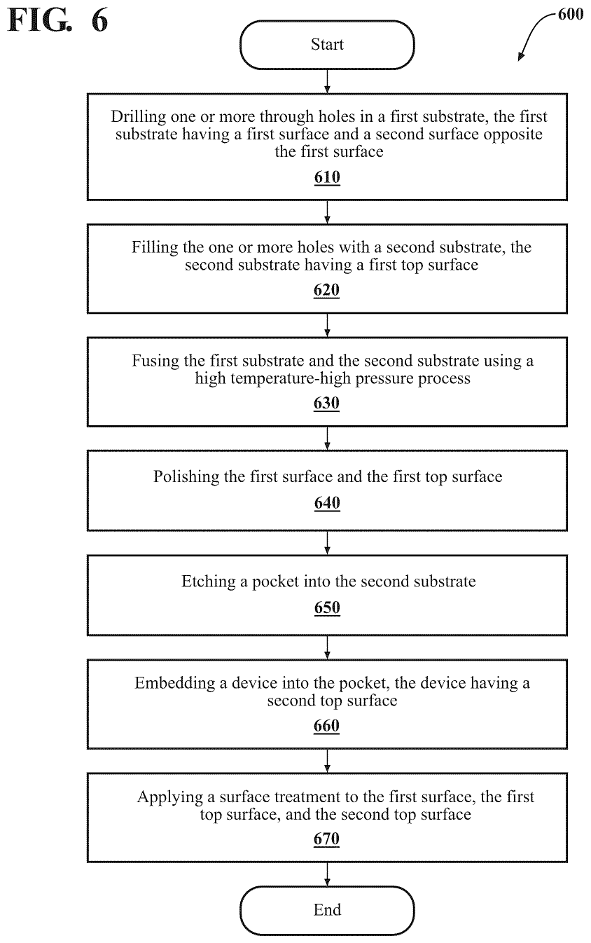

FIG. 6 is a flowchart illustrating one embodiment of a method 600 associated with generating a PCB assembly 100, 200, 300 that is receptive to 3D printed material.

At block 610, the method 600 includes drilling one or more through holes 110, 210 in a first substrate 104, 204. The first substrate 104, 204 has a first surface 106, 206 and a second surface 108, 208 opposite the first surface 106, 206. As previously mentioned, the first substrate 104 may be a resin, more specifically, a high temperature resin such as FR4. Alternatively, the first substrate 204 may be aluminum. The aluminum may be anodized. In such a case, the aluminum may be standard anodized on the first surface 206 and hard anodized on the second surface 208.

At block 620, the method 600 includes filling the one or more through holes 110, 210 with a second substrate 120, 220. The second substrate 120, 220 has a first top surface 124, 224. As an example, the second substrate 120, 220 may be copper or a copper composite. With the second substrate 120, 220 in the through hole 110, 210, there may be a gap 122, 222 within the through hole 110, 210 between the second substrate 120, 220 and the first substrate 104, 204. In a case where the first substrate 204 is aluminum, a third substrate 223 is placed in between the first and second substrates 204, 220.

At block 630, the method 600 includes fusing the first substrate 104, 204 and the second substrate 120, 220 using a high temperature-high pressure process. As an example and in a case where the first substrate 104 is a resin such as FR4 and the second substrate 120 is copper, the high temperature-high pressure process causes the resin to melt and adhere to the copper substrate. As another example and in a case where the first substrate 204 is a metal like aluminum, the second substrate 220 is a metal like copper, and the third substrate 223 is a resin like FR4 and is in the gap 222 between the first substrate 204 and the second substrate 220, the high temperature-high pressure process causes the third substrate 223 to melt and adhere to the first and second substrates 204, 220.

At block 640, the method 600 includes polishing the first surface 106 and the first top surface 124 using any suitable method such that the first surface 106 of the first substrate 104 and the first top surface 124 of the second substrate 120 are flush with each other. In case where the PCB assembly 200 includes a first substrate 204 that is metal, a second substrate 220 that is metal, and a third substrate 223 in between the first substrate 204 and the second substrate 220, the method 600 includes polishing the first surface 206, the first top surface 224, and a third top surface 227 of the third substrate 223 such that the first surface 206, the first top surface 224, and the third top surface 227 are flush with each other.

At block 650, the method 600 includes etching a pocket 126, 226 into the second substrate 120, 220. The pocket 126, 226 can house a device 128, 228 such as any suitable electronic device. The method 600 may include etching a pocket 126, 226 into the second substrate 120, 220 using any of the previously mentioned processes.

At block 660, the method 600 includes embedding a device 128, 228 into the pocket 126, 226. The device 128, 228 has a second top surface 130, 230. The device 128, 228 may be embedded into the pocket 126, 226 using any suitable process such as previously mentioned.

At block 670, the method 600 includes applying a surface treatment to the first surface 106, 206, the first top surface 124, 224, the second top surface 130, 230, and may include the third top surface 227. The surface treatment may roughen the first surface 106, 206, the first top surface 124, 224, and the second top surface 130, 230 such that the first surface 106, 206, the first top surface 124, 224, and the second top surface 130, 230 become adhesive such that 3D printed material can adhere to the first surface 106, 206, the first top surface 124, 224, and the second top surface 130, 230 without any unevenness between the 3D printed material and the first surface 106, 206, the first top surface 124, 224, and the second top surface 130, 230. The surface treatment may be applied to the third top surface 227 if in use. The surface treatment may include a laser etching process, a machine etching process, and/or a chemical process.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any kind of processing system or other apparatus adapted for carrying out the methods described herein is suited. A typical combination of hardware and software can be a processing system with computer-usable program code that, when being loaded and executed, controls the processing system such that it carries out the methods described herein. The systems, components and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises all the features enabling the implementation of the methods described herein and, which when loaded in a processing system, is able to carry out these methods.

Furthermore, arrangements described herein may take the form of a computer program product embodied in one or more computer-readable media having computer-readable program code embodied or embedded, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk drive (HDD), a solid state drive (SSD), a random access memory (RAM), a read-only memory (ROM), an erasable programmable read-only memory (EPROM or Flash memory), an optical fiber, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Program code embodied on a computer-readable medium may be transmitted using any appropriate medium, including but not limited to wireless, wireline, optical fiber, cable, RF, etc., or any suitable combination of the foregoing. Computer program code for carrying out operations for aspects of the present arrangements may be written in any combination of one or more programming languages, including an object oriented programming language such as Java™ Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

As used herein, the term “substantially” or “about” includes exactly the term it modifies and slight variations therefrom. Thus, the term “substantially equal” means exactly equal and slight variations therefrom. “Slight variations therefrom” can include within 15 percent/units or less, within 14 percent/units or less, within 13 percent/units or less, within 12 percent/units or less, within 11 percent/units or less, within 10 percent/units or less, within 9 percent/units or less, within 8 percent/units or less, within 7 percent/units or less, within 6 percent/units or less, within 5 percent/units or less, within 4 percent/units or less, within 3 percent/units or less, within 2 percent/units or less, or within 1 percent/unit or less. In some instances, “substantially” can include being within normal manufacturing tolerances.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e. open language). The phrase “at least one of . . . and . . . ” as used herein refers to and encompasses any and all possible combinations of one or more of the associated listed items. As an example, the phrase “at least one of A, B and C” includes A only, B only, C only, or any combination thereof (e.g., AB, AC, BC or ABC).

Aspects herein can be embodied in other forms without departing from the spirit or essential attributes thereof. Accordingly, reference should be made to the following claims, rather than to the foregoing specification, as indicating the scope of the invention.

What is claimed is:

1. A circuit board assembly comprising;
a first substrate having a first surface and a second surface opposite the first surface, the first substrate having one or more through holes;
a second substrate within the one or more through holes, the second substrate fusing to the first substrate using a high temperature-high pressure process, the second substrate having a first top surface and a pocket; and
one or more devices positioned within the pocket and having a second top surface that is flush with the first surface and the first top surface, the one or more devices bonding to the second substrate, the first surface, the first top surface, and the second top surface being adhesive due to a surface treatment.

2. The circuit board assembly of claim 1, further comprising a cooling assembly bonded to the second surface.

3. The circuit board assembly of claim 2, wherein the cooling assembly includes a cold plate, wherein the cold plate bonds to the second surface using an electrically insulated material.

4. The circuit board assembly of claim 1, wherein the first substrate is at least one of:
a resin;
a polymer;
ceramic;
glass;
an epoxy; or
a composite material of one or more of a resin, a polymer, ceramic, glass, or an epoxy.

5. The circuit board assembly of claim 1, wherein the second substrate is metal-based.

6. The circuit board assembly of claim 1, wherein the surface treatment is at least one of:
a laser treatment process;
a plasma treatment process;
a mechanical treatment process; or
a chemical treatment process.

7. The circuit board assembly of claim 1, further comprising a three dimensional (3D) printed layer fixed to the first surface, the first top surface, and the second top surface.

8. The circuit board assembly of claim 7, wherein the 3D printed layer includes at least one of:
a polymer-based ink;
a ceramics-based ink;
a metal-based ink; or
a carbon-based ink.

9. A circuit board assembly comprising;
a first substrate having a first surface and a second surface opposite the first surface, the first substrate having one or more through holes;
a second substrate within the one or more through holes, the second substrate having a first top surface and a pocket;
a third substrate filling a gap between the first substrate and the second substrate, the third substrate having a third top surface, the third substrate fusing to the first substrate and the second substrate using a high temperature-high pressure process; and
one or more devices positioned within the pocket and having a second top surface that is flush with the first surface, the first top surface, and the third top surface, the one or more devices being bonded to the second substrate, the first surface, the first top surface, the second top surface, and the third top surface being adhesive due to a surface treatment.

10. The circuit board assembly of claim 9, further comprising a cooling assembly bonded to the second surface.

11. The circuit board assembly of claim 10, wherein the cooling assembly includes a cold plate, wherein the cold plate bonds to the second surface using an electrically insulated material.

12. The circuit board assembly of claim 9, wherein the first substrate is an electrically-insulated metal due to treatment.

13. The circuit board assembly of claim 9, wherein the second substrate is metal-based.

14. The circuit board assembly of claim 9, wherein the third substrate is a resin.

15. The circuit board assembly of claim 9, wherein the surface treatment is at least one of:
a laser treatment process;
a plasma treatment process;
a mechanical treatment process; or
a chemical treatment process.

16. The circuit board assembly of claim 9, further comprising a 3D printed layer fixed to the first surface, the first top surface, the second top surface, and the third top surface.

17. The circuit board assembly of claim 16, wherein the 3D printed layer includes at least one of:
a polymer-based ink;
a ceramics-based ink;
a metal-based ink; or
a carbon-based ink.

18. A method, the method comprising:
drilling one or more through holes in a first substrate, the first substrate having a first surface and a second surface opposite the first surface;
filling the one or more through holes with a second substrate, the second substrate having a first top surface;
fusing the first substrate and the second substrate using a high temperature-high pressure process;
polishing the first surface and the first top surface;
etching a pocket into the second substrate;
embedding a device into the pocket, the device having a second top surface; and
applying a surface treatment to the first surface, the first top surface, and the second top surface.

19. The method of claim 18, further comprising:
bonding a cooling assembly to the second surface.

20. The method of claim 18, wherein the surface treatment is at least one of:
a laser treatment process;
a mechanical treatment process;
a plasma treatment process; or
a chemical treatment process.
